(19) United States
(12) Patent Application Publication
(10) Pub. No.: US 2007/0102718 A1
(43) Pub. Date: May 10, 2007

(54) Lens in light emitting device

(76) Inventors: Akira Takekuma, Tokyo (JP); Siew Kim Tan, Alor Setar (MY); Thye Linn Mok, Bukit Mertajam (MY)

Correspondence Address: AVAGO TECHNOLOGIES, LTD., P.O. BOX 1920, DENVER, CO, 80201-1920, US

(21) Appl. No.: 11/268,078

(22) Filed: Nov. 7, 2005

(51) Int. Cl. H01L 33/00

(52) U.S. Cl. 257/98

(57) ABSTRACT

In an embodiment, there is disclosed an opto-electronic package, comprising a substrate, a plurality of light emitting diode (LED) dice, and at least one lens disposed between the cavity-defining walls and having a maximum height remaining within an aperture of an elongate cavity of the substrate. In an embodiment, there is disclosed a system for backlighting an LCD screen, the system comprising an opto-electronic package and a light guide. A method of manufacturing an opto-electronic package is disclosed, the method comprising fabricating a substrate, attaching a plurality of light emitting diode (LED) dice to the base of the substrate within the cavity, and disposing at least one lens between the cavity-defining walls and entirely within the aperture of the elongate cavity.

### BACKGROUND

Referring to FIGS. 16-18, there is shown a side emitting light emitting diode (LED) package 5 for providing light to a light guide 10 (FIG. 18). Light guide 10 is typically used for backlighting of a liquid crystal display (LCD) (not shown) with LED package 5 as the light source for light guide 10.

Referring to FIG. 17, there is shown a cross-sectional view of LED package 5. Light emitting diode (LED) dice 15 are in attachment to the bottom of a substrate 20, and within walls 25 forming an elongate cavity 30. Generally, a transparent encapsulation material 35 is disposed inside of elongate cavity 30 to cover the LED dice 15. Transparent encapsulation material 35 may fill elongate cavity 30 to an aperture 40 formed by walls 25.

Typically, there are provided wire connects between an electrode on each one of LED dice 15 and bonding pads on substrate 20. On an outer surface of walls 25, electrodes may be electrically connected to a motherboard, and the pathway from the motherboard through the electrodes supplies electrical current to the LED dice 15. The number of LED dice 15 depends on the design of substrate 20 and light guide 10.

For side-emitting LED dice 15 used as a light source for light guide 10, LED package 5 is normally located very close to light guide 10 in order to avoid light loss between LED package 5 and light guide 10.

Normally, side emitting LED package 5 is designed to deliver as much light as possible to light guide 10. A convex lens may be mounted on the outer surface of the encapsulate material, and outside of aperture 40, to collimate light into a direction toward light guide 10. However, the configuration with the convex lens mounted on the outer surface of the encapsulate material is generally not recommended because some light goes through a side area of the convex lens and never goes into light guide 10.

Typically, LED package 5 contains red, green and blue (RGB) LED dice 15 in elongate cavity 30. Using RGB LED dice 15 as the light source for the backlight of light guide 10 into the LCD generally provides a wide color range, but requires an area for color mixing. If color mixing is accomplished inside of LED package 5, which generates mostly white light, light guide 10 will generally require a smaller area for color mixing. Controlling light from LED dice 15 in elongate cavity 30 is limited without the use of a convex lens outside of aperture 40, on encapsulation material 35.

A reflector cup within elongate cavity 30 may be provided in order to provide good color mixing without the use of a lens. The reflector cup acts to control the direction of light from one or more of LED dice 15. However, the reflector cup only controls the direction of light from the side of a die and does not control the direction of reflected light traveling in a direction from the top of the die through aperture 40.

Referring now to FIGS. 19 and 20, for a single die of LED dice 15 in LED package 5, there is shown a radiation pattern plot 45 for the LED (FIG. 19) and a schematic diagram of a ray trace simulation 50 in the vertical direction away from the die (FIG. 20). For radiation pattern plot 45 and ray trace simulation 50, side emitting LED package 5 is filled with transparent encapsulation material 35 and no lens is disposed in the light path. Transparent encapsulation material 50 fills the whole elongate cavity 30 of substrate 20 as shown in FIG. 17, only one die of dice 15 is activated, and the radiation pattern of plot 45 is measured at a location outside of LED package 5. On the vertical direction, viewing angle tends to be wide and radiation pattern has several peaks. This is due to the refraction of the light from the die at the flat surface of transparent encapsulation material 35, and the light is bent toward a far angle. Also, the reflected light that is reflected at the wall of housing goes to a direction with a larger angle from the 0 degree, on-axis direction.

### SUMMARY OF THE INVENTION

In an embodiment, there is provided an opto-electronic package comprising a substrate having a base and a plurality of cavity-defining walls, the base and the plurality of cavity-defining walls defining an elongate cavity having a major axis, a minor axis and an aperture, and the base having a surface that presents within the cavity; a plurality of light emitting diode (LED) dice mounted to the surface of the base that presents within the elongate cavity of the substrate so as to project light within the elongate cavity; and at least one lens disposed between the cavity-defining walls and having a maximum height remaining within the aperture of the elongate cavity, and the at least one lens having a convex orientation relative to at least one of the plurality of light emitting diode (LED) dice along the minor axis of the elongate cavity of the substrate.

In another embodiment, there is provided a system for backlighting an LCD screen, the system comprising an opto-electronic package, comprising a substrate having a base and a plurality of cavity-defining walls, the base and the plurality of cavity-defining walls defining an elongate cavity having a major axis, a minor axis and an aperture, and the base having a surface that presents within the cavity; a plurality of light emitting diode (LED) dice mounted to the surface of the base that presents within the elongate cavity of the substrate so as to project light within the elongate cavity; and at least one lens disposed between the cavity-defining walls and having a maximum height remaining within the aperture of the elongate cavity, and the at least one lens having a convex orientation relative to at least one of the light emitting diode (LED) dice along the minor axis of the elongate cavity of the substrate; a light guide having an input portion and an output portion, the input portion operatively associated with the aperture to receive light provided by the plurality of light emitting dice (LED) dice, and the output portion operatively associated with the LCD screen to transmit the light from the input portion to the LCD screen.

In another embodiment, there is provided a method of manufacturing an opto-electronic package, comprising fabricating a substrate having a base and a plurality of cavity-defining walls, the base and the plurality of cavity-defining walls defining an elongate cavity having a major axis and an aperture, the base having a surface that presents within the cavity; attaching a plurality of light emitting diode (LED) dice to the base of the substrate within the cavity; and disposing at least one lens between the cavity-defining walls and entirely within the aperture of the elongate cavity, and the at least one lens having a convex orientation relative to at least one of the plurality of light emitting diode (LED) dice along the minor axis of the elongate cavity of the substrate.

Other embodiments are also disclosed.

### BRIEF DESCRIPTION OF THE DRAWINGS

Illustrative embodiments of the invention are illustrated in the drawings, in which:

FIG. 1 illustrates an embodiment of an LED package for a light source;

FIG. 2 illustrates a cross-sectional view of the LED package shown in FIG. 1;

FIG. 3 illustrates a radiation pattern plot for an LED package shown in FIG. 1;

FIG. 4 illustrates a single lens disposed over a single LED die;

FIG. 5 illustrates a ray trace simulation in the horizontal direction for the LED die contained in the LED package shown in FIG. 1;

FIG. 6 illustrates a ray trace simulation in the vertical direction for the LED die contained in the LED package shown in FIG. 1;

FIG. 7 illustrates an embodiment of an LED package for a light source;

FIG. 8 illustrates a radiation pattern plot for an LED package shown in FIG. 7;

FIG. 9 a ray trace simulation in the vertical direction for the LED die contained in the LED package shown in FIG. 7;

FIGS. 10-13 illustrate an embodiment of an LED package manufactured with a jig;

FIG. 14 illustrates an embodiment of a system having an LED package with a lens disposed within the aperture to direct light into a light guide;

FIG. 15 is a flow diagram illustrating an embodiment of a method of manufacturing an LED package;

FIGS. 16 and 17 illustrate an LED package;

FIG. 18 illustrates a system having an LED package and a light guide;

FIG. 19 illustrates a radiation pattern plot for an LED package shown in FIG. 16;

FIG. 20 illustrates a ray trace simulation in the vertical direction for the LED die contained in the LED package shown in FIG. 16; and

FIGS. 21 and 22 illustrate an embodiment of an LED package for a light source having a dimpled surface.

### DETAILED DESCRIPTION OF AN EMBODIMENT

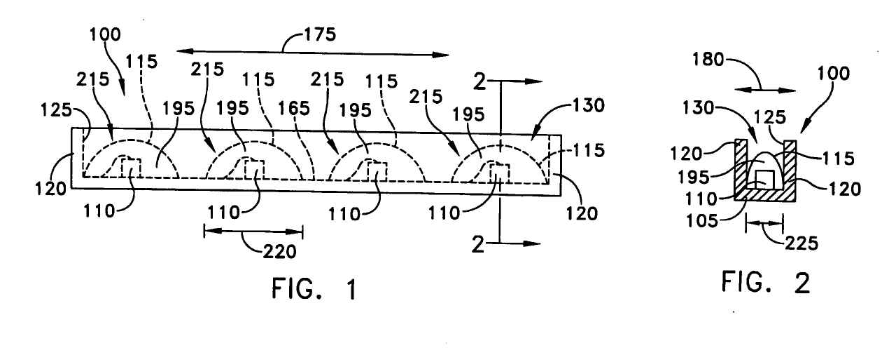

Looking at FIGS. 1, 2, and 7, and in an embodiment, there is shown an opto-electronic package 100 comprising a substrate 105, a plurality of light emitting diode (LED) dice 110, and at least one lens 115 disposed between cavity-defining walls 120 and having a maximum height remaining within an aperture 125 of an elongate cavity 130 of substrate 105.

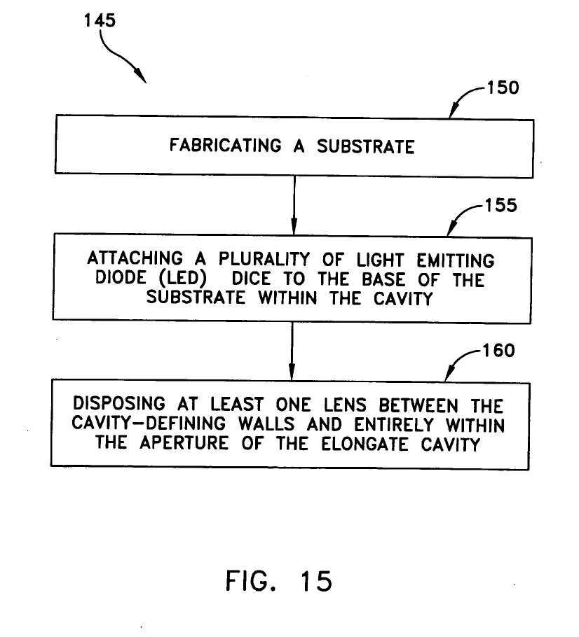

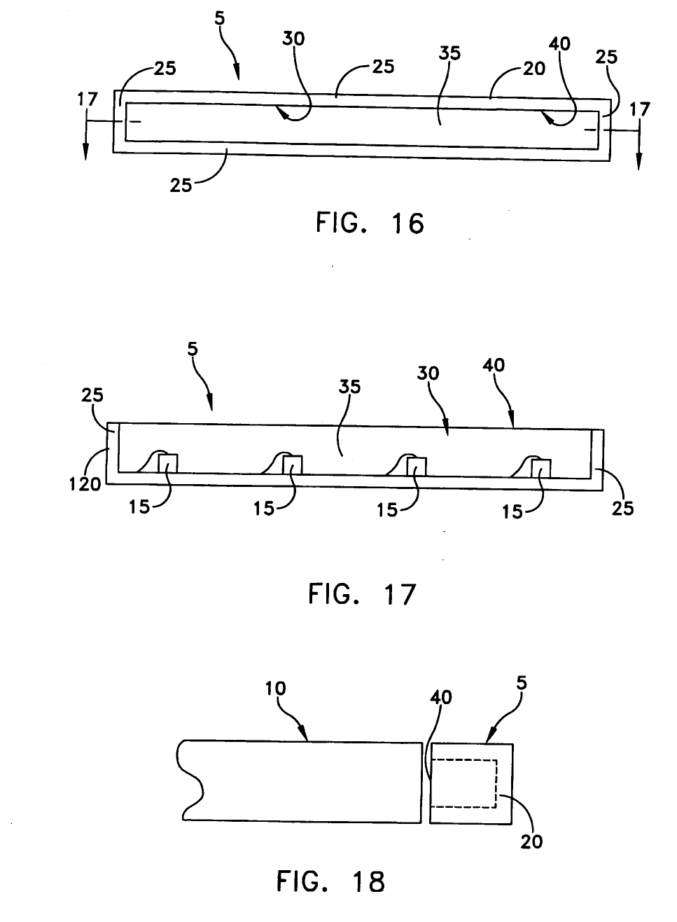

Referring to FIG. 15, and in one embodiment, there is disclosed a system 135 for backlighting an LCD screen. System 135 comprises opto-electronic package 100 and a light guide 140.

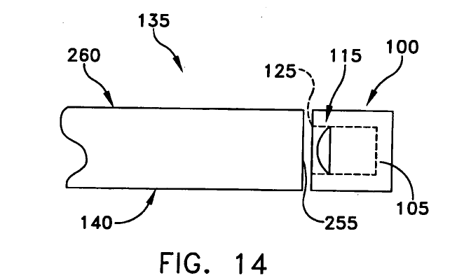

Referring now to FIG. 14, there is shown a method 145 of manufacturing an opto-electronic package. In an embodiment, the method comprises fabricating 150 a substrate, attaching 155 a plurality of light emitting diode (LED) dice to the base of the substrate within the cavity, and disposing 160 at least one lens between the cavity-defining walls and entirely within the aperture of the elongate cavity.

Referring again to FIGS. 1, 2 and 7, there is shown opto-electronic package 100 comprising substrate 105 having a base 165 and plurality of cavity-defining walls 120. Base 165 and plurality of cavity-defining walls 120 define an elongate cavity 170 having a major axis 175, a minor axis 180 and an aperture 185. Base 165 has a surface 190 that presents within cavity 170, and plurality of light emitting diode (LED) dice 110 are mounted to surface 190 of base 165 that presents within elongate cavity 130 of substrate 105 so as to project light within elongate cavity 130. At least one lens 115 is disposed between cavity-defining walls 120 and has a maximum height remaining within aperture 125 of elongate cavity 130. At least one lens 115 has a convex orientation relative to at least one of plurality of light emitting diode (LED) dice 110 along minor axis 180 of elongate cavity 130 of substrate 105.

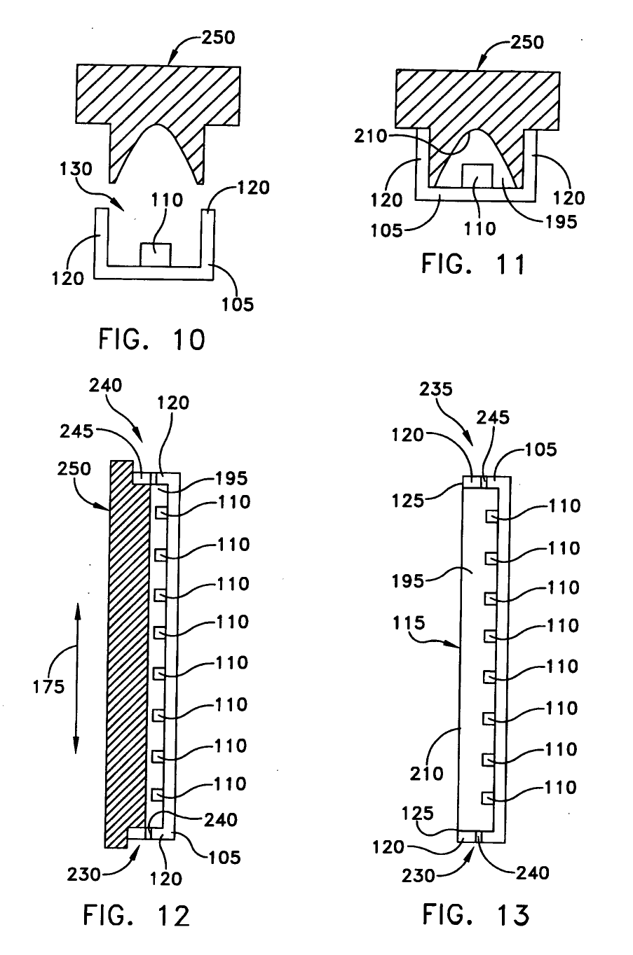

Looking at FIGS. 1, 2, 4, 5, 7, 12 and 13, and in an embodiment, at least one lens 115 may comprise an encapsulation material 195 disposed over light emitting diode (LED) 110 within elongated cavity 130. In one embodiment, encapsulation material 195 may comprise epoxy. In another embodiment, encapsulation material 195 may comprise silicone.

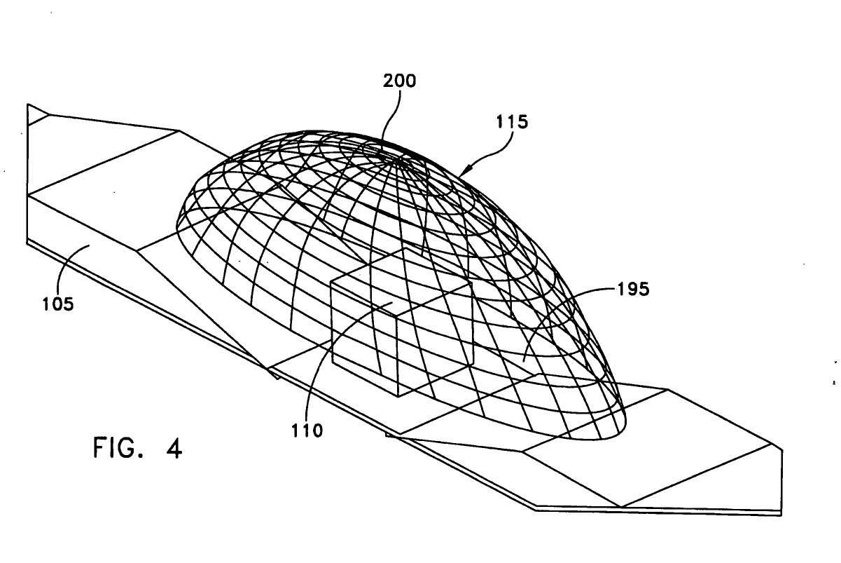

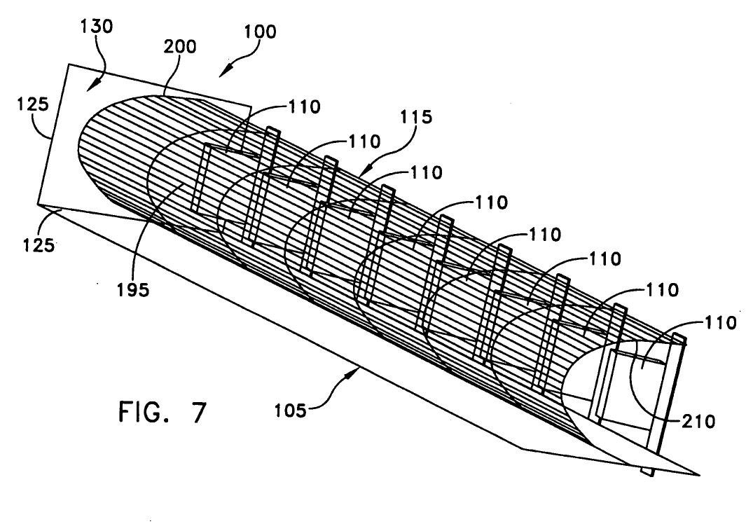

Referring to FIGS. 4 and 7, and in an embodiment, at least one lens 115 may optionally comprise a plastic lens 200 disposed over light emitting diode (LED) 115 within elongated cavity 130. In one embodiment, encapsulation material 195 may be disposed over light emitting diode (LED) 110 and within plastic lens 200. In one embodiment, encapsulation material 195 may comprise epoxy. In another embodiment, encapsulation material 195 may comprise silicone.

Looking at FIGS. 7 and 13, and in an embodiment, at least one lens 115 is a single lens 205 disposed over the plurality of light emitting diode (LED) dice 115. In one embodiment, single lens 205 is mounted to surface 190 of base 165 that presents within elongate cavity 130 of substrate 105. In one embodiment, single lens 205 may comprise encapsulation material 105 disposed over light emitting diode (LED) 110 within elongated cavity 130. In an embodiment, encapsulation material 195 may comprise epoxy. In another embodiment, encapsulation material 195 may comprise silicone.

Referring to FIG. 7, and in an embodiment, single lens 205 may comprise plastic lens 200 disposed over light emitting diode (LED) 110 within elongated cavity 130. In one embodiment, encapsulation material may be disposed over light emitting diode (LED) 110 and within plastic lens 200 of single lens 205. In an embodiment, encapsulation material 195 may comprise epoxy. In another embodiment, encapsulation material 195 may comprise silicone.

Looking again at FIGS. 7, 12 and 13, single lens 205 may comprise a substantially uniform cylindrical portion 210 having a substantially uniform height in a direction parallel to the major axis of the substrate.

Referring now to FIG. 1, and in an embodiment, there is shown at least one lens 115 comprising a plurality of lens portions 215. Corresponding ones of the plurality of light emitting diode (LED) dice 110 and ones of the plurality of lens portions 215 may be in operational association with one another, respectively. In one embodiment, plurality of lens portions 215 each comprise a first length 220 and a second length 225, the first length extending parallel to the major axis, the second length extending in a direction parallel to the minor axis, and the first length extending a longer distance than the second length.

Referring still to FIG. 1, each one of plurality of lens portions 215 are discrete from the other ones of the plurality of lens portions 215. In an embodiment, plurality of lens portions 215 each comprise encapsulation material 195 disposed over light emitting diode (LED) 110 within elongated cavity 130. In one embodiment, encapsulation material 195 may comprise epoxy. In another embodiment, encapsulation material 195 may comprise silicone.

In an embodiment, plurality of lens portions 215 each comprise plastic lens 200 disposed over light emitting diode (LED) 110 within elongated cavity 130. In one embodiment, encapsulation material 195 is disposed over light emitting diode (LED) 110 and within plastic lens 200. In an embodiment, encapsulation material 195 may comprise epoxy. In another embodiment, encapsulation material 195 may comprise silicone.

Referring to FIG. 13, and in an embodiment, the maximum height of at least one lens 115 is co-planar with aperture 125 of elongate cavity 130.

Referring to FIGS. 10-13, and in one embodiment, there is shown substrate 20 having a first end 230 and a second end 235 in opposition to one another along major axis 175, and wherein the cavity defining walls 120 define a first hole 240 therethrough at first end 230 and define a second hole 245 therethrough at second end 235. In an embodiment, substrate 105 comprises a plastic material. In another embodiment, substrate comprises a ceramic material.

In an embodiment, a jig 250 is selectively disposed within elongate cavity 130 for casting encapsulation material 195 so as to form one or more of the at least one lens 115.

Referring to FIG. 15, and in an embodiment, there is shown system 135 for backlighting an LCD screen. Light guide 140 generally includes an input portion 255 and an output portion 260. Input portion 255 may be operatively associated with aperture 40 to receive light provided by plurality of light emitting dice (LED) dice 110. Output portion 260 may be operatively associated with the LCD screen to transmit the light from input portion 255 to the LCD screen.

In an embodiment, there is provided a method of manufacturing an opto-electronic package. Generally, the method comprises fabricating a substrate having a base and a plurality of cavity-defining walls, the base and the plurality of cavity-defining walls defining an elongate cavity having a major axis and an aperture, the base having a surface that presents within the cavity. The method comprises attaching a plurality of light emitting diode (LED) dice to the base of the substrate within the cavity. The method comprises disposing at least one lens between the cavity-defining walls and entirely within the aperture of the elongate cavity, and the at least one lens having a convex orientation relative to at least one of the plurality of light emitting diode (LED) dice along the minor axis of the elongate cavity of the substrate.

In one embodiment, the method may comprise disposing the at least one lens between the cavity-defining walls and entirely within the aperture comprises disposing an encapsulation material over the plurality of light emitting diode (LED) dice within the elongated cavity, and curing the encapsulation material so as to form the at least one lens with the encapsulation material.

In relation to the step of disposing the at least one lens between the cavity-defining walls and entirely within the aperture comprises disposing a plastic lens over the plurality of light emitting diode (LED) dice within the elongated cavity, the method may comprise disposing an encapsulation material within the plastic lens and over the plurality of light emitting diode (LED) dice, and curing the encapsulation material so as to form the at least one lens with the plastic lens and the encapsulation material.

In relation to the step of disposing a jig through the aperture into the elongated cavity and over the plurality of light emitting diode (LED) dice, the method may comprise disposing an encapsulation material within the jig and over the plurality of light emitting diode (LED) dice, curing the encapsulation material so as to form the at least one lens with the encapsulation material, and removing the jig from the elongated cavity through the aperture.

The method may further comprise positioning the substrate to align the major axis in a vertical direction, and disposing the encapsulation material through a first hole defined in the first end into the elongated cavity within the jig and over the plurality of light emitting diode (LED) dice.

In one embodiment, lens 115 is created inside of elongate cavity 130, and the top of lens 115 does not extend from package 100. One convex lens 205 is applied to one die 110, and a curvature of lens 205 may be designed for each differing type of die 110.

For the horizontal direction parallel to major axis 175, light from LED die 110 spreads out and mixes with light from an adjacent die 115 in order to improve color mixing. For the vertical direction parallel to minor axis 180, light from LED die 110 focuses toward the central axis of light guide 140 for an increase in luminous intensity. In order to optimize color mixing and intensity, curvature for in the horizontal direction and in the vertical direction may be different from one another. A suitably sized aspherical oval lens may be used.

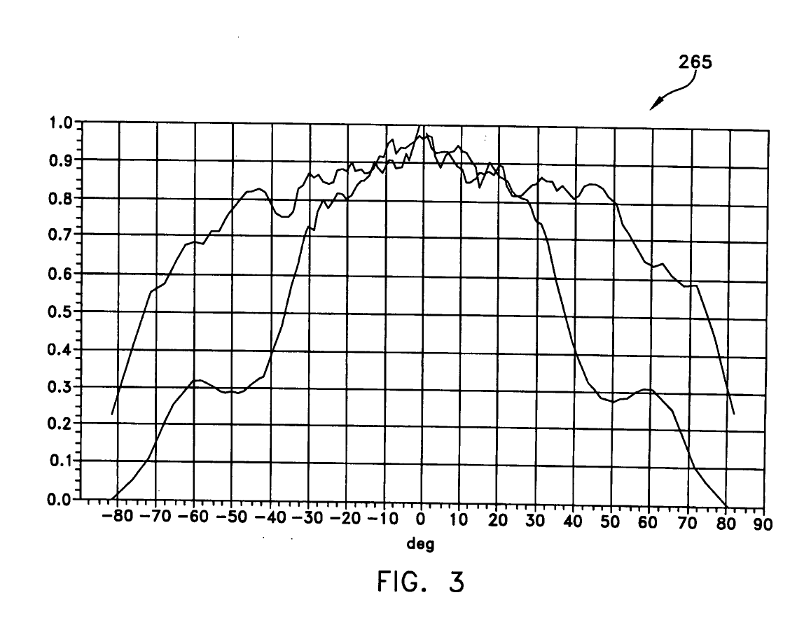

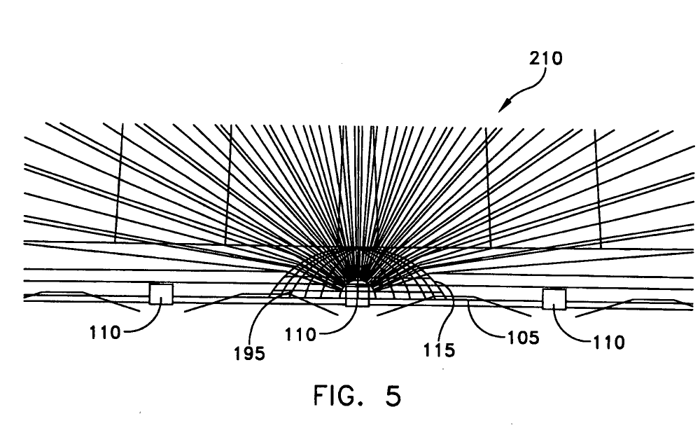

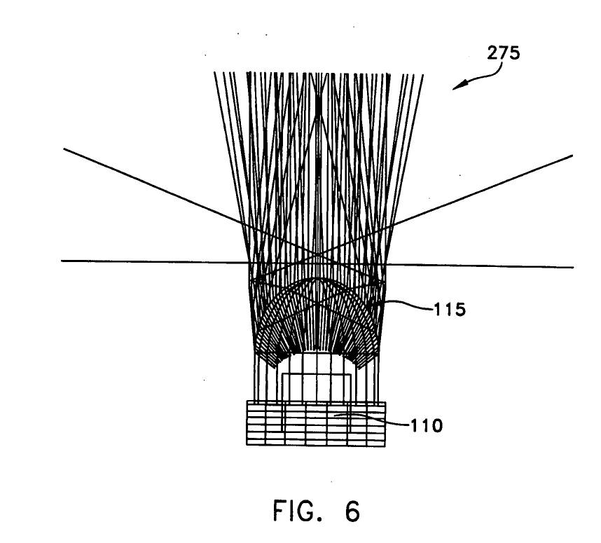

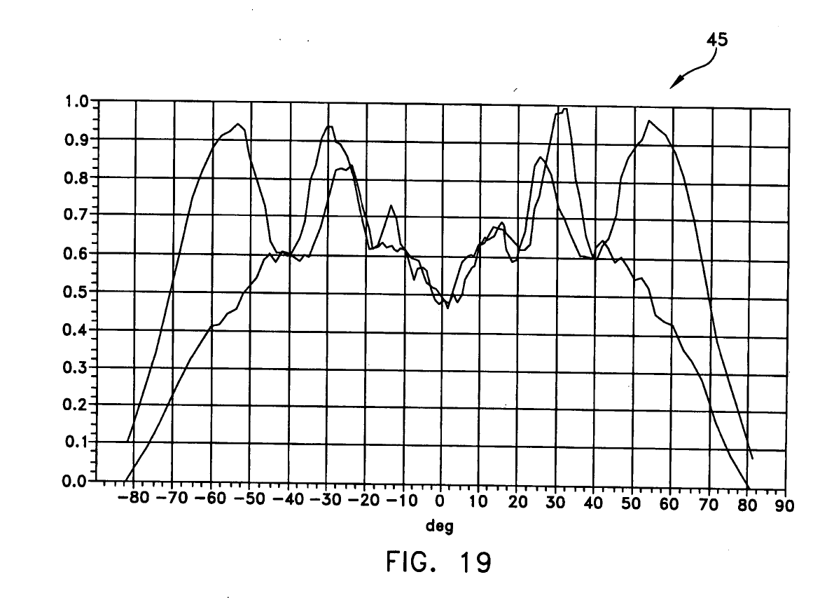

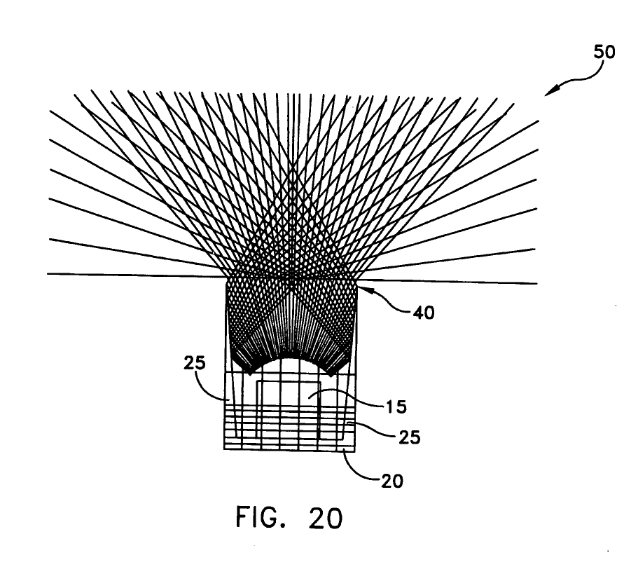

Referring to FIGS. 3, 5 and 6, for a single die of LED dice 110 in LED package 100 having an aspherical oval lens 115 as shown in FIG. 1, there is shown a radiation pattern plot 265 (FIG. 3) for the die, a schematic diagram of a ray trace simulation 270 (FIG. 5) in the horizontal direction and a schematic diagram of a ray trace simulation 275 (FIG. 6) in the vertical direction. The radiation pattern of the die is measured at the same position as the shown in FIGS. 19 and 20. The light on horizontal direction is spread out (FIG. 5) by lens 115 to produce a more uniform white color by mixing well with the other light from other ones of dice 110. In the vertical direction, the light is focused (FIG. 6) by lens 115 to reduce light loss at the coupling to a light guide.

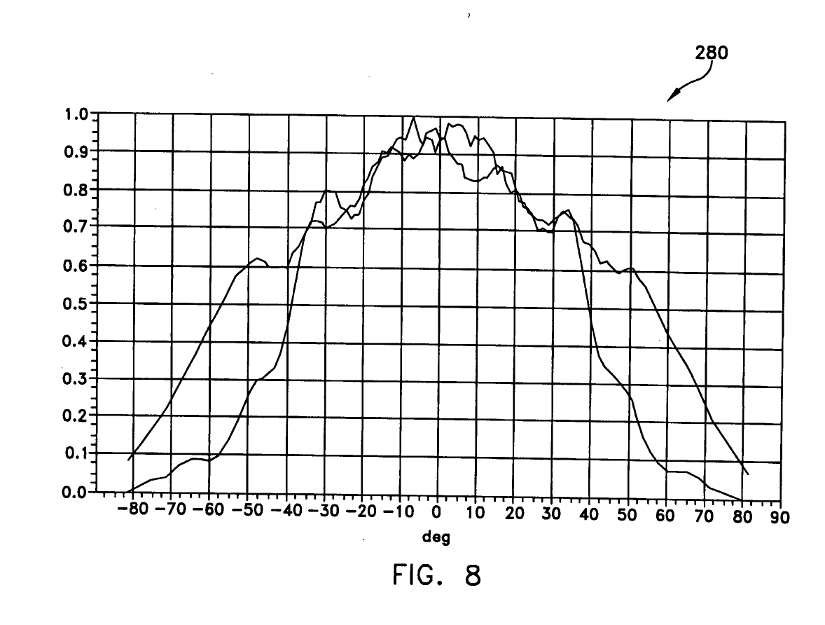

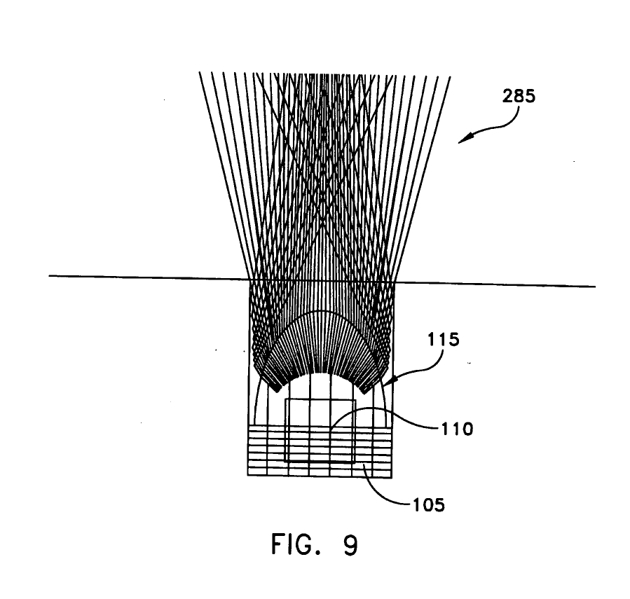

Referring now to FIGS. 8 and 9, for a single die of LED dice 110 in LED package 5 having a relatively uniform cylindrical portion lens 115 as shown in FIG. 7, there is shown a radiation pattern plot 280 (FIG. 8) for the die, a schematic diagram of a ray trace simulation 285 (FIG. 9) in the vertical direction. The radiation pattern of the die is measured at the same position as the shown in FIGS. 3, 5 and 6 and in FIGS. 19 and 20. This cylindrical lens 115 (FIG. 7) may be easier to fabricate than aspherical oval lens 115 while providing enough effect on the vertical direction of emitted light.

In order to maximize the effect of lens, the lens may be located at a far distance from the light source LED die, and the size of the lens may be sized relatively large in comparison to the size of the light source. However, the LED die size cannot be sized too small in order to maintain adequate brightness, and the aperture of the housing is normally limited at the width of the light guide for good light coupling. Within these constraints, the top of the lens may be located at the same position as the edge of the housing, and the size of the lens may be sized as large as possible within the aperture size of the substrate.

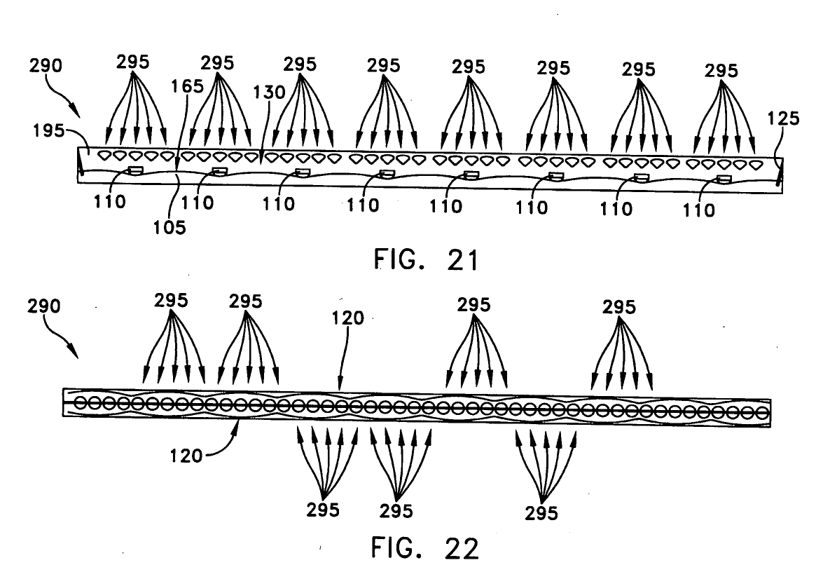

Referring now to FIGS. 21 and 22, and in one embodiment, there is shown an opto-electronic package 290 comprising substrate 105 having base 165 and plurality of cavity-defining walls 120. Base 165 and plurality of cavity-defining walls 120 define an elongate cavity 130 and an aperture 125. Base 165 has surface 190 that presents within cavity 130. Plurality of light emitting diode (LED) dice 110 may be mounted to surface 190 of base 165 that presents within elongate cavity 130 of substrate 105 so as to project light within elongate cavity 130. Encapsulation material 195 is disposed between cavity-defining walls 120 and has a maximum height remaining within aperture 125 of elongate cavity 130. Encapsulation material has a plurality of dimples 295 formed therein. In an embodiment, dimples 295 formed in an outer surface of encapsulation material 195 may include slight depressions or indentations to form a dimpled surface. In one embodiment, dimples have a radius of about 0.15 mm, a depth of about 0.15 mm, and a pitch of about 0.35 mm. Dimples 295 may be sized and located in encapsulation material 195 to increase the intensity of light through aperture 125.

In an embodiment, the substrate may be made of plastic or ceramics, and some pieces may be built on one sheet of plastic or ceramics in an array. Bond pads and electrodes may be made on the substrate using, for example, plating techniques on plastic or a known via hole techniques on ceramics. After attaching LED dice and connecting the die and wire bond pad with a gold wire, encapsulate material may be disposed into elongate cavity.

A jig which has a concave cavity may be used to create the convex lens shape on the encapsulate material during a process of curing the encapsulate material.

In an embodiment, the jig is attached on the housing prior to placement of the encapsulate material. The jig is preferably inserted into the elongate cavity and fixed into position along the wall of the substrate. In order to optimize alignment of the lens position to the die position, the jig may be pressed towards the housing during the process of placing and curing the encapsulate material.

In order to avoid an air bubble from the encapsulate material, the substrate is preferably held vertically and the encapsulate material is added through a hole located at a bottom position, and air is allowed to escape through another hole at a top position.

When the encapsulate material is fully filled, a residual amount of the material may escape the hole at the top position. This residual amount may remain at an outside area of the substrate. This residual amount may be removed by trimming after cure.

After curing the encapsulate material, the jig is removed, and each package is separated by sawing or snapping.

In an embodiment, convex lenses are fabricated as an array of plastic lenses separate from the package, and these pre-fabricated lenses are each subsequently attached to the substrate of the package. In an embodiment, after die attaching and wire bonding, a liquid type of transparent material is casted in the elongate cavity to cover the LED dice and wires. Before curing the transparent material, the plastic lenses of the array are attached inside of the substrate. The bottom surface of the lens may be either flat or convex shape to prevent an air bubble from being trapped under the bottom surface on top of the transparent material. Each of the lenses in the array may have a hole or a slit to allow escape of the residue of the transparent material. After attaching the lenses of the array, the transparent material may be cured in an oven.

What is claimed is:

1. An opto-electronic package, comprising:
a substrate having a base and a plurality of cavity-defining walls, the base and the plurality of cavity-defining walls defining an elongate cavity having a major axis, a minor axis and an aperture, and the base having a surface that presents within the cavity;
a plurality of light emitting diode (LED) dice mounted to the surface of the base that presents within the elongate cavity of the substrate so as to project light within the elongate cavity; and
at least one lens disposed between the cavity-defining walls and having a maximum height remaining within the aperture of the elongate cavity, and the at least one lens having a convex orientation relative to at least one of the plurality of light emitting diode (LED) dice along the minor axis of the elongate cavity of the substrate.

2. The package of claim 1, wherein the at least one lens comprises an encapsulation material disposed over the light emitting diode (LED) within the elongated cavity.

3. The package of claim 2, wherein the encapsulation material comprises epoxy.

4. The package of claim 2, wherein the encapsulation material comprises silicone.

5. The package of claim 1, wherein the at least one lens comprises a plastic lens disposed over the light emitting diode (LED) within the elongated cavity.

6. The package of claim 5, further comprising an encapsulation material disposed over the light emitting diode (LED) and within the plastic lens.

7. The package of claim 6, wherein the encapsulation material comprises epoxy.

8. The package of claim 6, wherein the encapsulation material comprises silicone.

9. The package of claim 1, wherein the at least one lens is a single lens disposed over the plurality of light emitting diode (LED) dice mounted to the surface of the base that presents within the elongate cavity of the substrate.

10. The package of claim 9, wherein the single lens comprises an encapsulation material disposed over the light emitting diode (LED) within the elongated cavity.

11. The package of claim 10, wherein the encapsulation material comprises epoxy.

12. The package of claim 10, wherein the encapsulation material comprises silicone.

13. The package of claim 9, wherein the single lens comprises a plastic lens disposed over the light emitting diode (LED) within the elongated cavity.

14. The package of claim 13, further comprising an encapsulation material disposed over the light emitting diode (LED) and within the plastic lens of the single lens.

15. The package of claim 14, wherein the encapsulation material comprises epoxy.

16. The package of claim 14, wherein the encapsulation material comprises silicone.

17. The package of claim 9, wherein the single lens comprises a substantially cylindrical portion having a substantially uniform height in a direction parallel to the major axis of the substrate.

18. The package of claim 1, wherein the at least one lens comprises a plurality of lens portions, corresponding ones of the plurality of light emitting diode (LED) dice and ones of the plurality of lens portions in operational association with one another, respectively.

19. The package of claim 18, wherein the plurality of lens portions each comprise a first length and a second length, the first length extending parallel to the major axis, the second length extending in a direction parallel to the minor axis, and the first length extending a longer distance than the second length.

20. The package of claim 19, wherein each one of the plurality of lens portions are discrete from the other ones of the plurality of lens portions.

21. The package of claim 18, wherein the plurality of lens portions each comprise an encapsulation material disposed over the light emitting diode (LED) within the elongated cavity.

22. The package of claim 21, wherein the encapsulation material comprises epoxy.

23. The package of claim 21, wherein the encapsulation material comprises silicone.

24. The package of claim 18, wherein the plurality of lens portions each comprise a plastic lens disposed over the light emitting diode (LED) within the elongated cavity.

25. The package of claim 24, further comprising an encapsulation material disposed over the light emitting diode (LED) and within the plastic lens.

26. The package of claim 25, wherein the encapsulation material comprises epoxy.

27. The package of claim 25, wherein the encapsulation material comprises silicone.

28. The package of claim 1, wherein maximum height of the at least one lens is co-planar with the aperture of the elongate cavity.

29. The package of claim 1, wherein the substrate has a first end and a second end in opposition to one another along the major axis, and wherein the cavity defining walls define a first hole therethrough at the first end and define a second hole therethrough at the second end.

30. The package of claim 1, wherein the substrate comprises a plastic material.

31. The package of claim 1, wherein the substrate comprises a ceramic material.

32. A system for backlighting an LCD screen, the system comprising:
an opto-electronic package, comprising:
a substrate having a base and a plurality of cavity-defining walls, the base and the plurality of cavity-defining walls defining an elongate cavity having a major axis, a minor axis and an aperture, and the base having a surface that presents within the cavity;
a plurality of light emitting diode (LED) dice mounted to the surface of the base that presents within the elongate cavity of the substrate so as to project light within the elongate cavity; and
at least one lens disposed between the cavity-defining walls and having a maximum height remaining within the aperture of the elongate cavity, and the at least one lens having a convex orientation relative to at least one of the light emitting diode (LED) dice along the minor axis of the elongate cavity of the substrate; and
a light guide having an input portion and an output portion, the input portion operatively associated with the aperture to receive light provided by the plurality of light emitting dice (LED) dice, and the output portion operatively associated with the LCD screen to transmit the light from the input portion to the LCD screen.

33. A method of manufacturing an opto-electronic package, comprising:
fabricating a substrate having a base and a plurality of cavity-defining walls, the base and the plurality of cavity-defining walls defining an elongate cavity having a major axis and an aperture, the base having a surface that presents within the cavity;
attaching a plurality of light emitting diode (LED) dice to the base of the substrate within the cavity; and
disposing at least one lens between the cavity-defining walls and entirely within the aperture of the elongate cavity, and the at least one lens having a convex orientation relative to at least one of the plurality of light emitting diode (LED) dice along the minor axis of the elongate cavity of the substrate.

34. The method of claim 33, wherein disposing the at least one lens between the cavity-defining walls and entirely within the aperture comprises disposing an encapsulation material over the plurality of light emitting diode (LED) dice within the elongated cavity, and curing the encapsulation material so as to form the at least one lens with the encapsulation material.

35. The method of claim 33, wherein disposing the at least one lens between the cavity-defining walls and entirely within the aperture comprises disposing a plastic lens over the plurality of light emitting diode (LED) dice within the elongated cavity, disposing an encapsulation material within the plastic lens and over the plurality of light emitting diode (LED) dice, and curing the encapsulation material so as to form the at least one lens with the plastic lens and the encapsulation material.

36. The method of claim 33, wherein disposing a jig through the aperture into the elongated cavity and over the plurality of light emitting diode (LED) dice, disposing an encapsulation material within the jig and over the plurality of light emitting diode (LED) dice, curing the encapsulation material so as to form the at least one lens with the encapsulation material, and removing the jig from the elongated cavity through the aperture.

37. The method of claim 36, further comprising positioning the substrate to align the major axis in a vertical direction, and disposing the encapsulation material through a first hole defined in the first end into the elongated cavity within the jig and over the plurality of light emitting diode (LED) dice.

38. An opto-electronic package, comprising:
a substrate having a base and a plurality of cavity-defining walls, the base and the plurality of cavity-defining walls defining an elongate cavity and an aperture, and the base having a surface that presents within the cavity;
a plurality of light emitting diode (LED) dice mounted to the surface of the base that presents within the elongate cavity of the substrate so as to project light within the elongate cavity; and
encapsulation material disposed between the cavity-defining walls and having a maximum height remaining within the aperture of the elongate cavity, the encapsulation material having a plurality of dimples formed therein.
